(19) United States
(12) Patent Application Publication
(10) Pub. No.: US 2007/0029993 A1
(43) Pub. Date: Feb. 8, 2007

(54) Automatic electric discharge tool

(75) Inventors: Shun-Hsien Chao, Taipei (TW); Chung-Wen Huang, Taipei (TW); Hung-Sheng Wang, Taipei (TW)

Correspondence Address: BACON & THOMAS, PLLC, 625 SLATERS LANE, FOURTH FLOOR, ALEXANDRIA, VA, 22314, US

(73) Assignee: INVENTEC CORPORATION, Taipei (TW)

(21) Appl. No.: 11/198,178

(22) Filed: Aug. 8, 2005

(51) Int. Cl. G01R 1/02

(52) U.S. Cl. 324/130

(57) ABSTRACT

The present invention is to provide an automatic electric discharge tool, which comprises a control unit and an energy consuming module, wherein the control unit electrically coupled to a plurality of energy storage devices to receive information signals sent and obtain the remaining power capacity, remaining power supply time and battery voltage of the energy storage device; and the energy consuming module electrically respectively coupled to the control unit and energy storage device in purpose to receiving and consuming the power of each energy storage device, furthermore, the control unit determines and then sends a switch signal to make the energy consuming module to stop consuming the power of the energy storage device when the power capacity dropping to 60% of the total power capacity.

### FIELD OF THE INVENTION

The present invention relates to an automatic electric discharge tool, and more particularly to an automatic electric discharge tool adapted with an energy consuming module to achieve automatically electric discharge.

### BACKGROUND OF THE INVENTION

In general, a power supply used for the operations of traditional notebook computers comes from a power transformer or a smart battery installed in the notebook computers, and notebook computer manufacturers usually perform repeated long-hour tests to assure a reliable quality of each notebook computer after the notebook computers are manufactured and assembled, and then deliver the notebook computers to distributors or consumers. Such arrangement not only reduces the rate of defective goods, but also improves the add-on value of a brand by high quality.

Further, manufacturers always pre-charge the smart battery of the notebook computers before shipping the computers to distributors or consumers, and also restrict the power capacity of the smart battery within a range of 40% to 60% of the power capacity. Such arrangement facilitates distributors to sell the goods or consumers to purchase the goods, since it requires no additional power supply and does not need to look for an electric socket for public demonstrations or operations. On the other hand, the goods travel a long distance via air freight, sea freight or land transportation during their shipments, and it is difficult to handle the environmental factors including the atmospheric pressure, temperature and humidity, and thus the smart battery is situated at a very unstable environment. If the power capacity of the smart battery is saturated, battery explosions or battery leaks may occur easily. If the power capacity of the smart battery is restricted within 40% to 60% of the total power capacity, then the battery will be safe for the use by distributors and consumers.

Referring to FIG. 1, the method for charging a smart battery according to a prior art includes the step of:

(101) connecting the notebook computer with the power transformer first, and then charging the smart battery (for about two hours);

(102) detaching the power transformer to stop charging the smart battery after the smart battery is fully charged;

(103) executing a high power consuming software (such as 3D animations) on the notebook computer, so that the performance of a central processing unit (CPU) of the notebook computer is fully used, and the power of the smart battery is consumed gradually;

(104) entering into a sleep mode, so that the computer no longer consumes power in the smart battery, if the notebook computer detects the power capacity of the smart battery dropping to 60% of the original total power capacity (which takes about an hour); and

(105) turning on the notebook computer by a tester of the notebook computer to confirm if the power capacity of the smart battery is maintained in the range from 40% to 60% of the total power capacity; if yes, then the notebook computer is turned off and shipped to the distributor or consumer, or else go to Step (101).

However, the foregoing method used for discharging the smart battery takes about several hours to charge/discharge the battery, and also requires many testers to test a large quantity of shipments in order to avoid delayed shipments. Each set of notebook computers has to go through the foregoing procedure, which not only makes the operation complicated, but also takes much time, more tests and causes higher costs.

Since the method for discharging a smart battery uses the full performance of the central processing unit to improve the power consumption of the notebook computer, the power capacity of the smart battery can be consumed gradually. However, this method is not perfect, because the performance of the central processing unit is fully used. In other words, the central processing unit produces lots of heat energy which will in advance consume each component and circuit in the notebook computer, and thus reducing the normal life of the computer after consumers buy the computer. Therefore, a design for overcoming the foregoing shortcomings and improving an automatic electric discharge tool becomes an important issue that demands immediate attentions.

### SUMMARY OF THE INVENTION

In view of the shortcomings of the foregoing method of discharging a smart battery of a notebook computer, the inventor of the present invention based on years of experience and professional knowledge to solve the problems and invent an automatic electric discharge tool, such that the smart battery can be discharged automatically to a certain power capacity and then automatically stop discharging, so as to reduce manufacturing cost and improve the discharging speed. Further, the invention does not have any adverse effect on each component and circuit in the notebook computer.

Therefore, it is a primary objective of the present invention to provide an automatic electric discharge tool that can gradually consume the power of a plurality of energy storage devices (such as smart batteries) at the same time, and will stop consuming the power of the energy storage device when the power capacity is dropped to 60% of the total power capacity of the energy storage device.

Another objective of the present invention is to provide an automatic electric discharge tool that comprises a control unit electrically coupled to the energy storage device through a communication module for receiving an information signal issued by the energy storage devices to obtain the information such as the remaining power capacity of the energy storage devices, the remaining power supply time and the battery voltage, etc.

Another further objective of the present invention is to provide an automatic electric discharge tool that comprises a display module electrically coupled to a display module for displaying the information such as the remaining power capacity of the energy storage device, and etc.

Another objective of the present invention is to provide an automatic electric discharge tool that comprises an energy consuming module for receiving and consuming the power of the energy storage devices that are connected to the tool.

The above and other objects, features and advantages of the present invention will become apparent from the following detailed description taken with the accompanying drawings.

### BRIEF DESCRIPTION OF THE DRAWINGS

FIG. 1 is a flow chart of a traditional battery discharge method; and

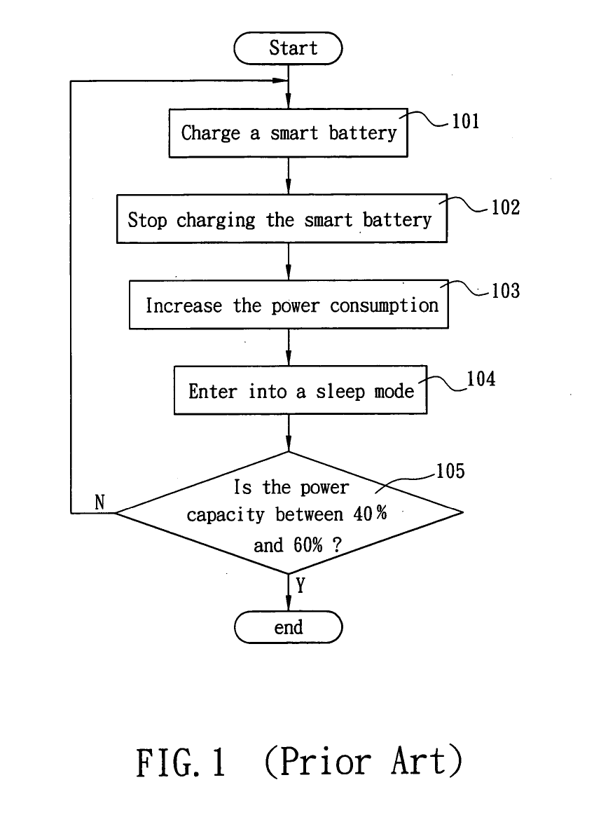

FIG. 2 is a circuit block diagram of a tool of the present invention.

### DETAILED DESCRIPTION OF THE PREFERRED EMBODIMENTS

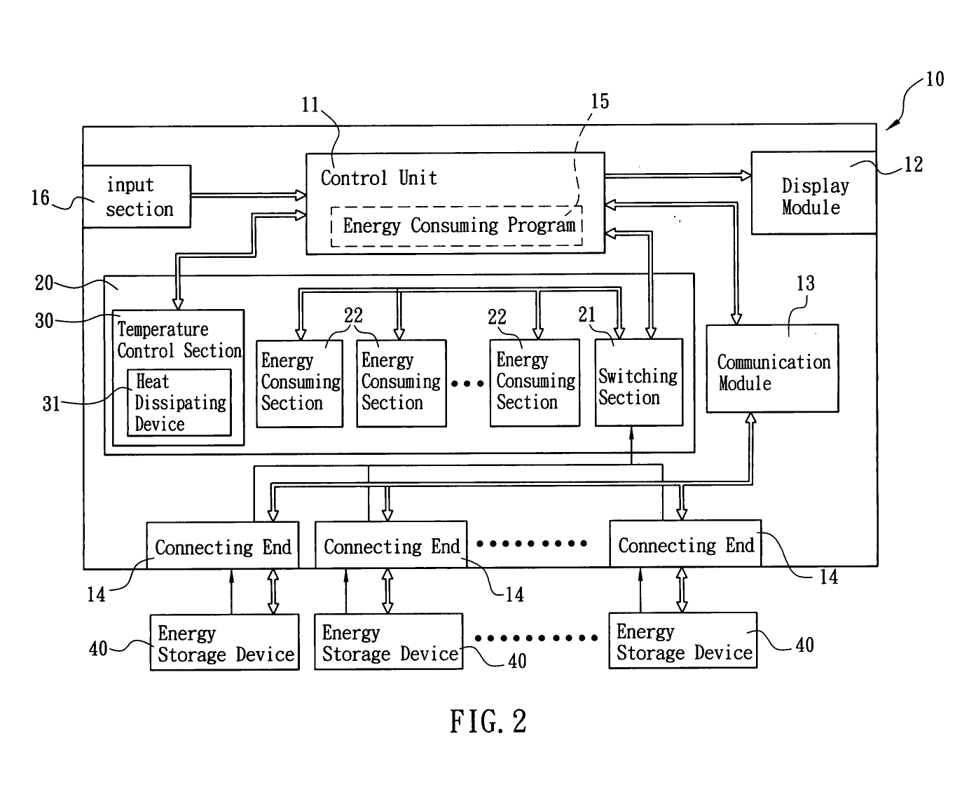

Referring to FIG. 2 for the automatic electric discharge tool of the present invention, the tool comprises a control unit 11, a display module 12, a communication module 13 (which can be built in the control unit 11), and at least one connecting end 14. The control unit 11 is provided for connecting each component and circuit in the tool 10, such that the tool 10 can work properly. The display module 12 is electrically coupled to the control unit 11, such that the display module 12 can receive a display signal sent by the control unit 11, and the status in a form of texts, signs or hints is displayed for the viewing of an operator. The communication module 13 is coupled separately with the control unit 11 and each connecting end 14 for receiving a control signal sent by the control unit 11, and the control signal is sent to the energy storage device 40 (such as a smart battery) connected to the connecting ends through each connecting end 14, so as to obtain an information signal sent from the energy storage devices 40 and then send the information signal to the control unit 11. After the control unit 11 has received the information signals, the information including the remaining power capacity, remaining power supply time and battery voltage of the energy storage device 40 can be obtained and displayed on the display module 12.

Referring to FIG. 2, the foregoing display module 12 could be a liquid crystal display (LCD) and/or a plurality of light emitting diodes (LED). The liquid crystal display is used to display texts, numbers and symbols, and the change of color of the light emitting diode is used to indicate the status of the energy storage device 40. For example, if no energy storage device 40 is connected to the tool, then all light emitting diodes will be off. The light emitting diode can be used to indicate the status of discharging, approaching a set value of the power capacity, completing discharging, and being over-discharged, so that operators can quickly and conveniently know about the status of the tool 10 and each energy storage device 40 by viewing the light emitting status of the light emitting diodes.

In the present invention, the tool 10 further comprises an energy consuming module 20 electrically coupled to the control unit 11 for receiving a switch signal sent by the control unit 11, and the energy consuming module 20 also can be electrically coupled to each energy storage device 40 directly or indirectly (through the connecting end 14), so that the power capacity of each energy storage device 40 can be decreased gradually. Referring to FIG. 2, the control unit 11 installs an energy consumption program 15 that provides a predetermined power capacity for the setup by operators. The set value of the power capacity according to the present invention is a percentage of the total power capacity of each energy storage device 40 (such as 70% of the total power capacity, 60% of the total power capacity, or 30% of the total power capacity). After an energy storage device 40 is electrically coupled to the tool 10, the energy consumption program 15 will continue analyzing and determining the information signals of the energy storage device 40, such that if the remaining power capacity is equal to the predetermined power capacity, the energy consuming module 20 is controlled to stop consuming the power of the energy storage device 40, and the display module 12 will display the remaining power capacity of the energy storage device 40.

The energy consuming module 20 in accordance with a preferred embodiment of the present invention comprises a switching section 21 and a plurality of energy consuming sections 22; wherein the switching sections 21 receive a switch signal of the control unit 11 for switching the power of each energy storage device 40 and determining whether or not to transmit the power to the corresponding energy consuming section 22. If yes, then each energy consuming section 22 gradually consumes the power of each corresponding energy storage device 40, or else the power capacity of each energy storage device 40 remains unchanged. The energy consuming sections 22 are mutually connected to a plurality of resistors in parallel (or in series) to facilitate the computation of the resistance of the current flowing through the energy consuming sections 22, and further convert the power into heat energy. Therefore, the power of the energy storage devices 40 can be consumed gradually and accurately. The resistors according to a preferred embodiment of the invention are comprised of a plurality of low-power (such as 1 watt) resistors connected in parallel with each other, so that the heat produced by the energy consuming section 22 can be evenly dissipated to all resistors and the life of the energy consuming sections 22 can be extended.

In the invention, the tool 10 is electrically coupled to an energy storage device 40 in the following modes as shown in FIG. 2.

If the power capacity of the energy storage device 40 exceeds the predetermined value of the power capacity, the control unit 11 will issue a switch signal indicating “connection” to the switching section 21. After the switching section 21 has received such switch signal, the power of the energy storage device 40 is transmitted into the corresponding energy consuming section 22. In the meantime, the control unit 11 sends a display signal indicating an “ongoing process” to be displayed on the display module 12. Therefore, the energy consuming section 22 continues consuming the power of the energy storage device 40 until the remaining power capacity of the energy storage device 40 equals to the predetermined value of the power capacity.

If the power of the energy storage device 40 is equal to the predetermined value of the power capacity, then the control unit 11 will send out a switch signal indicating “disconnection” to the switching section 21. After the switching section 21 has received such switch signal, the power of the energy storage device 40 is disconnected from the corresponding energy consuming section 22. The energy consuming section 22 cannot obtain or consume the power of the energy storage device 40, therefore, the power capacity of the energy storage device 40 remains unchanged. In the meantime, the control unit 11 sends out a display signal indicating “good product” to be displayed on the display module 12.

If the power of the energy storage device 40 is lower than the predetermined value of the power capacity, then the control unit 11 will send out a switch signal indicating “disconnection” to the switching section 21. After the switching section 21 has received such switch signal, the power of the energy storage device 40 is disconnected from the corresponding energy consuming section 22, and the control unit 11 sends out a display signal indicating “defect” to be displayed on the display module 12.

The tool 10 further comprises an input section 16 electrically coupled to the control unit 11 for producing a corresponding input signal and sending the input signal to the energy consumption program 15, so as to control the tool 10. In a preferred embodiment of the present invention, the input section 16 provides at least three fixed operating modes for operator's choice such as 60%, 50% and 40%. By selecting any one of the modes, the tool 10 is controlled to consume the power of each energy storage device 40 while maintaining the power capacity. No matter how many modes are provided by the input section 16 or how the external structure and functions of the input section 16 are changed, the input section 16 for controlling the power capacity of each energy storage device 40 is intended to be covered by the scope of the present invention as far as the input section 16 can be operated by the operator.

The energy consuming module 20 further comprises a temperature control section 30 for detecting the temperature of the heat energy produced by the energy consuming section 22 and sending the temperature to the control unit 11 for the energy consumption program to analyze and determine whether or not the temperature has reached a critical value. If yes, the control unit 11 starts (or increase the power on a heat dissipating device 31 such as a fan or a heat sink in the temperature control section 30 to lower the internal temperature of the tool 10, or else the control unit 11 continues analyzing and determining whether or not a critical temperature has reached. The abovementioned critical value is predetermined by the manufacturer of the tool 10 according to the heat resistance of the tool 10 and the electronic components or set in the energy consumption program 15 by the operator of the tool 10, so as to extend the use life of the tool 10.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. An automatic electric discharge tool, comprising:
a control unit, for connecting each component and circuit in said tool to enable said tool to be operated normally, and said control unit including an energy consumption program for providing a predetermined value of a power capacity;
a display module, electrically coupled to said control unit for displaying a display signal sent from said control unit;
at least one connecting end, for coupling to a corresponding energy storage device;
a communication module, separately coupled to said control unit and said each connecting end for receiving a control signal of said control unit, and sending said control signal to said corresponding energy storage device through said connecting end, and information signals of said energy storage devices being received through said each connecting end and returned to said control unit for said energy consumption program to analyze said information of said energy storage device and display said information on said display module; and
an energy consuming module, electrically coupled to said control unit for receiving a switch signal of said control unit and said energy consuming module being electrically coupled to said each energy storage device for receiving and consuming the power of said each energy storage device until the power capacity of said each energy storage device equals to the predetermined value of said power capacity.

2. The tool of claim 1, wherein the predetermined value of said power capacity is a percentage of the total power capacity of said each energy storage device.

3. The tool of claim 1, wherein said communication module is built in said control unit.

4. The tool of claim 1, wherein said display module is a liquid crystal display or a plurality of light emitting diodes.

5. The tool of claim 1, wherein said energy consuming module comprises:
a switching section, for receiving a switch signal sent by said control unit for switching the power of said each energy storage device and determining whether or not the power is sent to said corresponding energy consuming section;
a plurality of energy consuming sections for gradually consuming the power after receiving the power of said corresponding energy storage device.

6. The tool of claim 5, wherein said energy consuming sections are comprised of a plurality of resistors connected in parallel with each other.

7. The tool of claim 5, wherein said control unit sends out a switch signal indicating a connection to said switching section, if the power capacity of said energy storage device exceeds the predetermined value of said power capacity, and after said switching section has received said switch signal, the power of said energy storage device is sent to a corresponding energy consuming section, such that said energy consuming section continues consuming the power of said energy storage device.

8. The tool of claim 5, wherein said control unit sends out a switch signal indicating a disconnection to said switching section, if said power capacity of said energy storage device equals to the predetermined value of said power capacity, and after said switching section has received said switch signal, the power of said energy storage device is disconnected from said corresponding energy consuming section.

9. The tool of claim 5, wherein said control unit sends a switch signal indicating a disconnection to said switching section if the power of said energy storage device is lower than the predetermined value of said power capacity, and after said switching section has received said switch signal, the power of said energy storage device is disconnected from said corresponding energy consuming section.

10. The tool of claim 1, further comprising an input section electrically coupled to said control unit for producing an input signal and sending said input signal to said control unit for controlling said tool.

11. The tool of claim 1, wherein said energy consuming module further comprises a temperature control section for detecting a temperature of the heat produced by said energy consuming sections and sending said temperature to said control unit for said energy consumption program to analyze and determine whether or not said temperature has reached a critical value; if said critical temperature is reached, a heat dissipating device in said temperature control section will be started to lower the internal temperature of said tool.
